(19) United States
(12) Patent Application Publication
(10) Pub. No.: US 2016/0028354 A1
(43) Pub. Date: Jan. 28, 2016

(54) SOUND-PLAYING BOARD

(71) Applicant: MEICHA FURNITURE CO., LTD., FAN YUAN HSIANG (TW)

(72) Inventors: Yu-Kai CHEN, FAN YUAN HSIANG (TW); Chuang-Chi KANG, FAN YUAN HSIANG (TW); JOY JONES, FAN YUAN HSIANG (TW)

(21) Appl. No.: 14/541,948

(22) Filed: Nov. 14, 2014

(30) Foreign Application Priority Data
Jul. 24, 2014 (TW) 103213148

(51) Int. Cl. H03F 3/181; H04R 1/02

(52) U.S. Cl. CPC H03F 3/181; H04R 1/025

(57) ABSTRACT

A sound-playing board includes a main body and a displaying unit. The main body contains therein a chamber and the main body has a surface provided with an amplifier window communicated with the chamber. The displaying unit has an amplifier and a communication interface. The amplifier is exposed at the amplifier window of the main body. The communication interface is deposited on the surface of the main body and is connected to the amplifier. With the combination of the internal chamber in the main body and the displaying unit, the sound-playing board is capable of playing sound. By using the sound-playing board as a tabletop of a table, the most part of the surface of the main body can be left for load-bearing use or other usage, and the integrated design forms no obstruction to people working or walking around the table, thereby being convenient.

### BACKGROUND OF THE INVENTION

1. Technical Field

The present invention relates to functional boards, and more particularly to a sound-playing board that can be used as a part of a piece of furniture while playing audio signals.

2. Description of Related Art

For a person who is eating, reading or working before a table and wants to listen to music, audio teaching contents or other audio contents, a conventional way is to place and operate a sound playing device on the table or on the ground under the table.

However, if the sound playing device is placed on the table, it can take considerable tabletop space and inconvenience the person's operation. Also, the played sound may resonate the tabletop and make the person uncomfortable. On the other hand, if the sound playing device is placed on the ground under the table, the distance may degrade the listening experience, and there is a risk that people may get tripped by the sound playing device and injured from falling or the sound playing device may be kicked and damaged.

### SUMMARY OF THE INVENTION

The primary objective of the present invention is to provide a sound-playing board, which maximizes spatial utilization and provides excellent sound-displaying quality.

For achieving the foregoing objective, the disclosed sound-playing board comprises a main body and a displaying unit. The main body contains therein a chamber, and the main body has its surface provided with an amplifier window that is communicated with the chamber. The displaying unit has an amplifier and a communication interface. The amplifier is exposed at the amplifier window of the main body. The communication interface is deposited on the surface of the main body and is electrically connected to the amplifier. Thereby, the disclosed sound-playing board has audio signals transmitted to the amplifier through the communication interface, and the amplifier uses the air in the chamber as a medium to transmit sound. By using the sound-playing board as a tabletop of a table, the most part of the surface of the main body can be left for load-bearing use or other usage, and the integrated design forms no obstruction to people working or walking around the table, thereby being convenient.

In one embodiment of the present invention, the main body has a fixing seat, a top plate, and a bottom plate. The fixing seat contains the chamber. The top plate covers the fixing seat from above and has the amplifier window. The bottom plate covers the fixing seat from below.

In one embodiment of the present invention, the fixing seat of the main body further has a receiving socket provided adjacent to the chamber. The displaying unit further has a buffering member that is received in the receiving socket for absorbing resonance of the board caused when the amplifier plays sound.

In one embodiment of the present invention, the bottom plate of the main body has a sound hole communicated with the chamber, for releasing vibrations generated in the air within the chamber when the amplifier plays sound.

### BRIEF DESCRIPTION OF THE DRAWINGS

FIG. 1 is a perspective view of the present invention.

FIG. 2 is an exploded view of the present invention.

FIG. 3 is an applied view of the present invention.

### DETAILED DESCRIPTION OF THE INVENTION

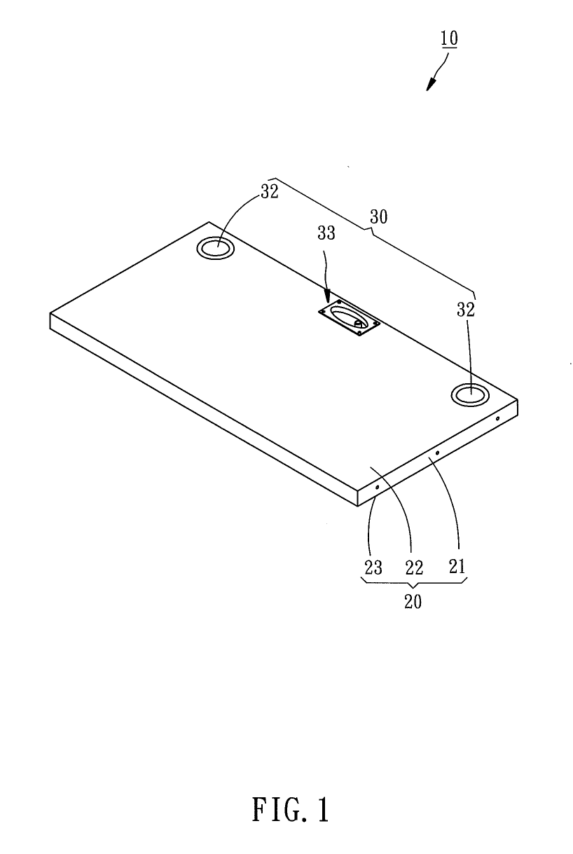

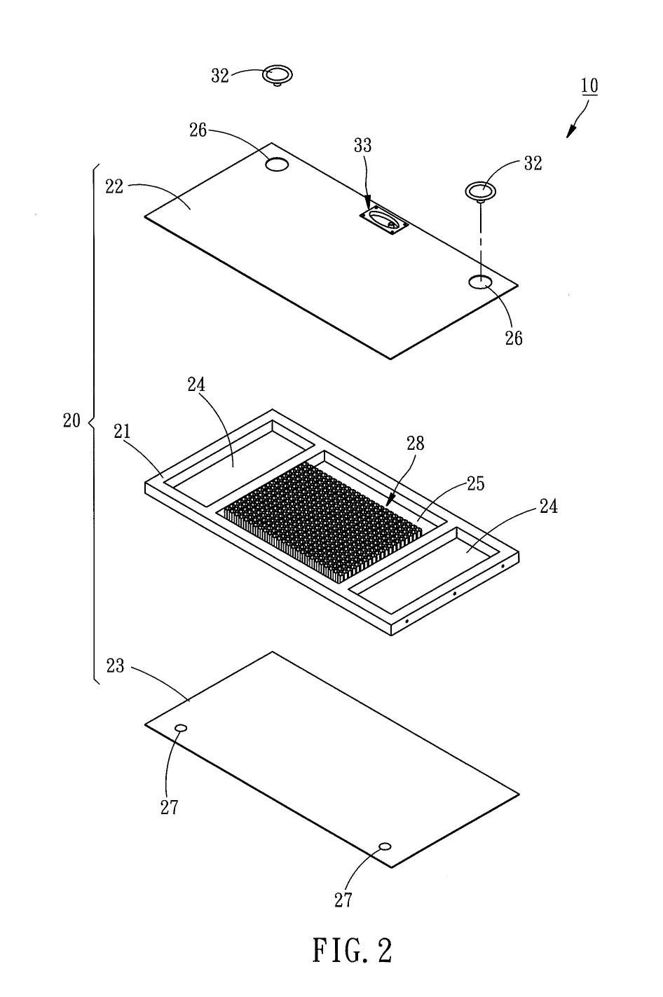

Referring to FIG. 1 and FIG. 2, according to the present invention, a sound-playing board 10 has a main body 20 and a displaying unit 30.

The main body 20 has a fixing seat 21, a top plate 22, and a bottom plate 23. The fixing seat 21 has two chambers 24 formed neat its two ends and the fixing seat 21 is centrally provided with a receiving socket 25 that is between the two chambers 24. The top plate 22 covers the fixing seat 21 from above and has two amplifier windows 26. Each of the amplifier windows 26 is communicated with the corresponding chamber 24 in the fixing seat 21. The bottom plate 23 covers the fixing seat 21 from below so that the fixing seat 21 is sandwiched between the top and bottom plates 22, 23, making the chambers 24 and the receiving socket 25 sealed from the exterior. The bottom plate 23 is provided with two sound holes 27 at its two ends. Each of the sound holes 27 is communicated with the corresponding chamber 24 in the fixing seat 21. In addition, the main body 20 has a buffering member 28 that is received in the receiving socket 25 of the fixing seat 21.

The displaying unit 30 has two amplifiers 32 and a communication interface 33. The amplifiers 32 are such installed on the main body 20 that they are exposed at the amplifier windows 26 of the top plate 22. The communication interface 33 is deposited on the surface of the top plate 22 of the main body 20 and is connected to the two amplifiers 32 for transmitting audio signals to the amplifiers 32. It is to be noted that the communication interface 33 may be a wireless communication interface (e.g. Bluetooth) or a wired communication interface, without limitation.

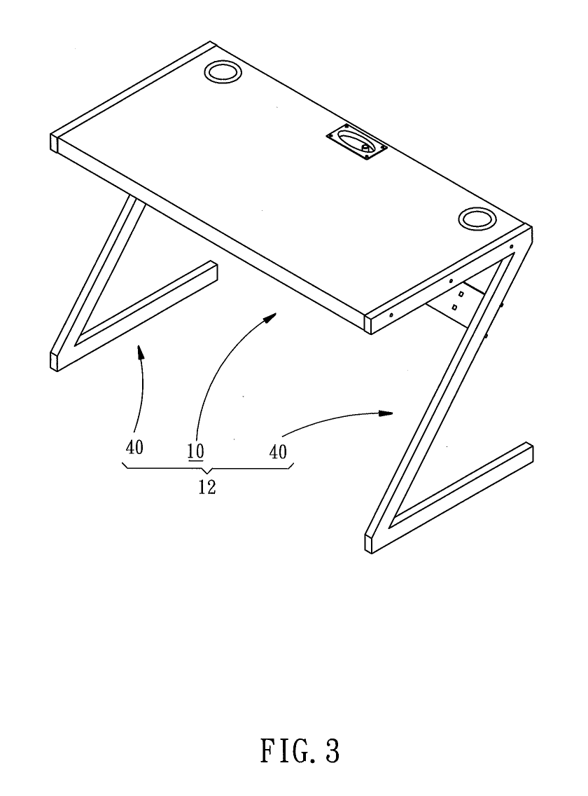

In operation, the disclosed sound-playing board 10 uses the communication interface 33 to transmit the audio signals input by a user to the amplifiers 32. The amplifiers 32 then use the air in the chambers 24 of the main body 20 as a medium to transmit sound. With the foregoing configuration, the usable area of the surface of the main body 20 can be maximized, and the audio signals can be conveniently played without hindering people walking around the furniture using the disclosed sound-playing board 10. In addition, when sound is displayed through the amplifiers 32, the sound holes 27 at the bottom plate 23 of the main body 20 serve to properly release vibrations generated in the air within the chamber 24. Moreover, the buffering member 28 serves to absorb the resonance generated by the main body 20, so as to mitigate the discomfort imposed on the user. Thus, the disclosed sound-playing board 10 can be added with table legs 40 to form a table 12 for general use (as shown in FIG. 3). Alternatively, it can be used as a tabletop of a kitchen counter, a tabletop of a dining table or a door plank of a closet, so the disclosed sound-playing board 10 is versatile.

What is claimed is:

1. A sound-playing board, comprising:
a main body, containing therein a chamber and having a surface provided with an amplifier window that is communicated with chamber; and
a displaying unit, including an amplifier and a communication interface, wherein the amplifier is exposed at the amplifier window of the main body, and the communication interface is deposited on the surface of the main body and is electrically connected to the amplifier.

2. The sound-playing board of claim 1, wherein the main body has a fixing seat containing the chamber, a top plate covering the fixing seat from above and having the amplifier window, and a bottom plate covering the fixing seat from below.

3. The sound-playing board of claim 2, wherein the fixing seat of the main body further comprises a receiving socket adjacent to the chamber, and the main body further comprises a buffering member that is received in the receiving socket.

4. The sound-playing board of claim 2, wherein the bottom plate of the main body has a sound hole that is communicated with the chamber.
